(19) United States
(12) Patent Application Publication
(10) Pub. No.: US 2026/0246465 A1
(43) Pub. Date: Aug. 20, 2026

(54) Micro/Nano Electromechanical Systems Based Complementary Logic Structures Utilizing Multi-Gate Relays

(71) Applicant: VIRGINIA COMMONWEALTH UNIVERSITY, Richmond, VA (US)

(72) Inventors: Bennett SMITH, Midlothian, VA (US); Md Ataul MAMUN, Richmond, VA (US); Benjamin HORSTMANN, Richmond, VA (US); Ümit ÖZGÜR, Chesterfield, VA (US); Vitality AVRUTIN, Henrico, VA (US)

(21) Appl. No.: 19/332,905

(22) Filed: Sep. 18, 2025

Related U.S. Application Data
(60) Provisional application No. 63/696,012, filed on Sep. 18, 2024.

(51) Int. Cl. H03K 19/08

(52) U.S. Cl. CPC H03K 19/08

(57) ABSTRACT

Description includes complementary multi-gate (MG) relay nano/microelectromechanical (N/MEMS) relay logic device, having a drain element, a parallel network of R N/MEMS relays, and a multi-gate N/MEMS relay. The logic device receives an R-bit input signal, and the signal multi-gate N/MEMS relay and the parallel network of R N/MEMS relays. The multi-gate N/MEMS relay, responsive to all bits concurrently at the logical 1 voltage state, coupled the drain element to a first reference voltage. The parallel network of R N/MEMS relays, collectively, connects a second reference voltage to the drain element if any of the R bits is logic 1 state. This is complementary to the response of the multi-gate N/MEMS relay. The multi-gate N/MEMS relay and the parallel network, in combination maintain the critical path and the shortest path equal, irrespective of R.

### CROSS REFERENCE TO RELATED APPLICATIONS

This application claims benefit of U.S. Provisional Application 63/696,012 filed Sep. 18, 2024, the complete contents of which are incorporated herein by reference.

### BACKGROUND

Complementary Metal Oxide (CMOS) based logic circuits are used in a wide variety of instrumentation and control system applications. In some applications, though, CMOS can have technical shortcomings. For example, in some environments with high electromagnetic interference and ionizing radiation, CMS can show less than desired resistance to degradation. Another is that CMOS's range of safe operating temperature can, for some applications, e.g., satellites and nuclear power plants, require temperature control measures with power consumption and weight costs. Also, CMOS scaling can produce increases in device power consumption, due, for example, to leakage current increase and deterioration of device sub-threshold characteristics.

However, NEMS/MEMS logic has certain technical issues. In a series network, using a series of N/MEMS relays and a complementary network of parallel connected N/MEMS relays adding another input requires another relay in the series. This adds another resistance and capacitance to the device propagation path, which has negative effect on device characteristics.

### SUMMARY

This Summary presents example features and aspects and is not an exclusive or exhaustive description of disclosed subject matter. Whether or not a feature is included in this Summary is not intended as an indication of the feature's relative importance or benefit.

One example multi-gate nano/microelectromechanical (N/MEMS) relay logic device configured to receive a multi-bit input signal and output a logic result, the device comprising a drain element, which can be conductive. N/MEMS multiple gate (MG) relay, configured to couple to a first reference voltage, and to receive a multi-bit input signal, each bit switchable between a logic “0” voltage and a logic “1” voltage and, responsive to a concurrence of logic 1 voltage on all bits of the multi-bit input signal, to couple the first reference voltage to the drain element. A complementary network comprising a plurality of N/MEMS relays, configured to couple to a second reference voltage and, responsive to states of the multi-bit input signal having other than concurrence of logic 0 on all bits, to couple the second reference voltage to the drain element. The N/MEMS MG relay may include a source element, which is conductive and coupled to the first reference voltage a cantilever arm. The cantilever arm may be conductively coupled via the source element to the first reference voltage. According to various embodiments, the cantilever arm can be configured as elastically bendable, from a cantilever arm resting state spaced from the drain element to a cantilever arm deflected state contacting the drain element. There may be R separate gate elements, each may be configured as conductive, R being an integer greater than one. The R separate gate elements can be arranged proximally to and spaced from the MG cantilever arm, and each may be configured to receive a corresponding different bit among the R bits of the multi-bit input signal. The cantilever arm and the R separate gate elements may be further and mutually configured such that each bit of the multi-bit input that is at logic 1 voltage establishes an incremental pulling force between the rth separate gate element that receives the bit and the cantilever arm, the incremental pulling force being based, at least in part, on the difference between the logic 1 voltage and the first reference voltage, —concurrence of Q bits of the multi-bit input at logic 1 voltage establishes a concurrence of a respective Q of the incremental pulling forces, which combine to be a total pulling force, —responsive to Q being less than R, the total pulling force is insufficient to pull the cantilever arm from the MG cantilever arm resting state to the cantilever arm deflected state, and—responsive to Q being equal to R, the total pulling force is sufficient to pull the cantilever arm from the MG cantilever arm resting state to the cantilever arm deflected state, contacting the drain element, and—the complementary network comprises a plurality of N/MEMS relays, connected in parallel, each having an N/MEMS relay source connector that is coupled to the second reference voltage and each configured to receive a corresponding one of the bits of the multi-bit input signal and, in response to occurrence of any state of the multi-bit input having at least one of the bits at logic 1, to couple the second reference voltage to the drain element.

### BRIEF DESCRIPTION OF DRAWINGS

A further understanding of the nature and advantages of the embodiments may be realized by reference to the following drawings. It will be understood that the drawings show illustrative, not limitative, features and examples. It will also be understood that the drawing graphics are scaled for readability and that graphic representations of functions and features are not necessarily drawn to a scale consistent with their physical implementations. Also, in the drawings, similar components or features may have the same reference label.

FIG. 1 shows a top view of one structure arrangement of for a selectively configurable, multi-configuration, multi-gate (MG) relay, micro/nano electromechanical systems (N/MEMS) logic device according to various embodiments.

FIG. 2 shows a top view of one two-input complementary NOR gate configuration of the FIG. 1 arranged multi-configuration, MG relay N/MEMS logic device according to various embodiments.

FIG. 3 shows a top view of one two-input complementary NAND gate configuration of the FIG. 1 arranged multi-configuration, MG relay N/MEMS logic device according to various embodiments.

FIG. 4A shows a top view of a complementary NOT gate configuration of the FIG. 1 arranged multi-configuration, MG relay N/MEMS logic device according to various embodiments.

FIG. 4B shows a top view of a simplified complementary NOT gate functional representation of the provided functionality of the FIG. 4 complementary NOT gate configured multi-configuration, MG relay N/MEMS logic device according to various embodiments.

FIG. 5 shows a top view a structure arrangement for a single 3-gate MG relay according to various embodiments, in a pull-up resistor based as 3-input NAND arrangement according to some embodiments.

FIG. 6 shows a scanning electron microscope (SEM) image of one inventor-produced sample MEMS scale selectively configurable, multi-configuration MG relay N/MEMS logic device according to various embodiments.

FIG. 7 shows a SEM image of one inventor-produced sample of a 3-gate MG relay according to various embodiments.

FIG. 8A shows a top view of an example complementary NOT gate configured N/MEMS device, with a step-down cantilever-based output, given an input of “0.” with the output measured using a low voltage cantilever, with illustrates the voltage across the floating drain terminal and ground when the high voltage cantilever is pulled in and released.

FIG. 8B shows a top view of an example complementary NOT gate configured N/MEMS device, with a step-down cantilever-based output, given an input of “1.”

FIG. 9 shows a graphical plot presenting computed cantilever time-to-release plots, computed using inventor-obtained measurements applying three different bias voltages.

FIG. 10 shows, by voltage verses time plots aligned above a common time axis, a plot of input voltage versus time and a plot of output voltage verses time of inventor-obtained measurements used for computing the FIG. 9 plots.

FIG. 11 shows, by a directed-arrow snapshot type sequence of progressing structures, one example fabrication process for producing multigate N/MEMS relays according to various embodiments.

FIG. 12 shows a cross-sectional SEM image of an etched NEMS scale trench produced in an inventor-performed fabrication of structure of construction of a N/MEMS relay according to one or more embodiments.

FIG. 13 shows a top view of one scale selectively configurable, multi-configuration MG relay N/MEMS scale logic device according to various embodiments.

FIG. 14 shows input and output signals of a two input OR gate using intermediate pad charging cycles.

FIG. 15 shows inventor-obtained test results from a testing of intermediate voltage preemptive charging of a drain element of an inventor-fabricated test sample.

FIG. 16 shows OR gate states of the FIG. 15 tested sample.

### DETAILED DESCRIPTION

It will understood that the terms “drain”, “drain element”, “source(s)”, “source element(s)”, “gate(s)”, “gate element(s)”, “cantilever”, and “cantilever arm”, as used herein to mean “conductive drain”, “conductive drain element”, “conductive source(s)”, “conductive source element(s)”, “conductive gate(s)”, “conductive gate element(s)”, “conductive cantilever”, and “conductive cantilever arm”, except for instances where expressly stated to have different meaning or clearly implied to have a different meaning.

A complementary multi-gate (MG) relay nano/microelectromechanical (N/MEMS) relay logic device according to some embodiments can include a drain element, a parallel network of R N/MEMS relays, R being an integer, and a multi-gate N/MEMS relay according to various embodiments. The complementary MG relay N/MEMS relay logic device can be configured to receive an R-bit input signal, R being an integer, and to feed the R-bit input signal to the multi-gate N/MEMS relay and to the parallel network of R N/MEMS relays.

According to various embodiments the multi-gate N/MEMS relay can connect to a first reference voltage and, based on the R bit states of the of the R-bit input signal, conditionally switch to an On state, and the On state establishes a connection from the first reference floatage to the drain element. According to various embodiments, the condition can be all R bits being, concurrently, at the logical 1 voltage state. Correspondingly, responsive to any state other than all R bits being logic 1, the multi-gate N/MEMS relay can maintain in an Off state.

A significant technical feature of the multi-gate N/MEMS relay, which will be appreciated by persons of ordinary skill from reading this disclosure in its entirety, is that the relay switch-on time of the multi-gate N/MEMS relay is one, meaning integer one, relay time.

According to various embodiments the parallel network of R N/MEMS relays can, collectively, provide a response to the R-bit input that is complementary to the response of the multi-gate N/MEMS relay. The response, according to various embodiments, is that if any of the R bits is logic 1 state, the parallel network of R N/MEMS relays establishes an On connection from a second reference voltage to the drain element.

Also, the delay time of the parallel network of R N/MEMS relays is one, i.e., integer one. The delay of the complementary MG relay N/MEMS relay logic device is therefore one, irrespective of the value of R.

The R N/MEMS relays in the parallel network can each include a respective gate element and a respective cantilever arm. Each of the R gate elements can be configured to receive a respective bit of the R-bit input. Each of the R bits can switch between a logic 0 and a logic 1 voltage state. Each of the R cantilever arms can be elastically bendable and, via an parallel network source connection, the R cantilever arms can be biased to a first reference voltage. In each of the R N/MEMS relays of the parallel network the respective gate element can be positioned and arranged relative to the respective cantilever element such that a difference between the first reference voltage, at which the cantilever arms are biased, and the respective input bit voltage on the relay's gate element can produce a pulling force between the gate element and the cantilever, which is sufficient to bend the cantilever element to a deflected state at which a surface of the cantilever element contacts the drain element. This results in the drain element being charged to the first reference voltage.

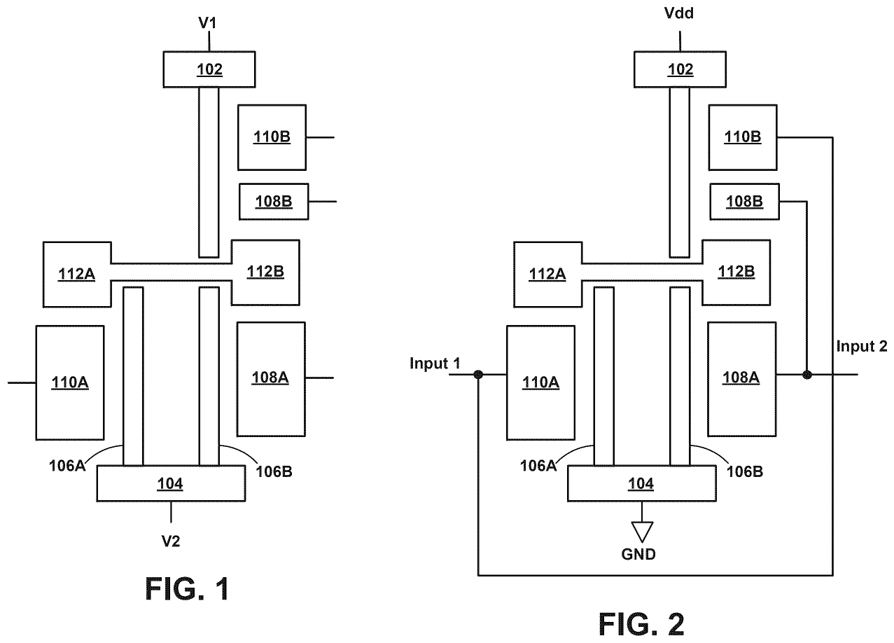

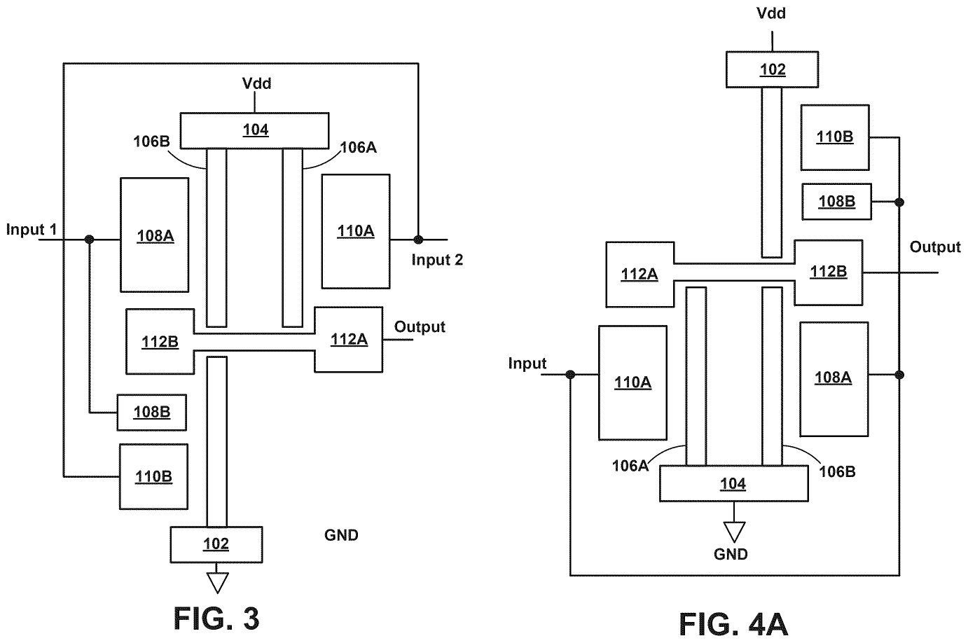

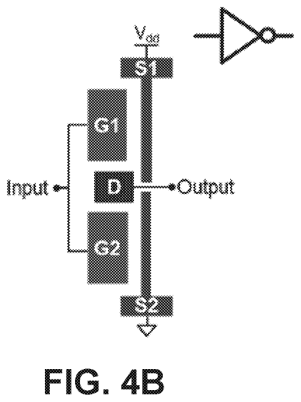

Referring to FIGS. 1, 2, and 3 each of the devices exhibit an identical architecture, featuring two networks of relays with opposing cantilever biases, as shown in FIG. 2 and FIG. 3, respectively. The first network comprises relays arranged in parallel, connecting sources and drains to respective nodes. The second network, forming the complement of the first, organizes relays in a series configuration, where the drain of one cantilever is linked to the source of the next. The number of relays in each network corresponds to the logic gate's input count, with each input directed to the gate of a single relay in both networks. In the FIG. 3 NAND logic, the series-configured relays are biased to a low voltage, pulling down the output, while the parallel network with high bias provides a pulled-up output. Applying opposite biases to each network results in a NOR gate, illustrated in FIG. 2.

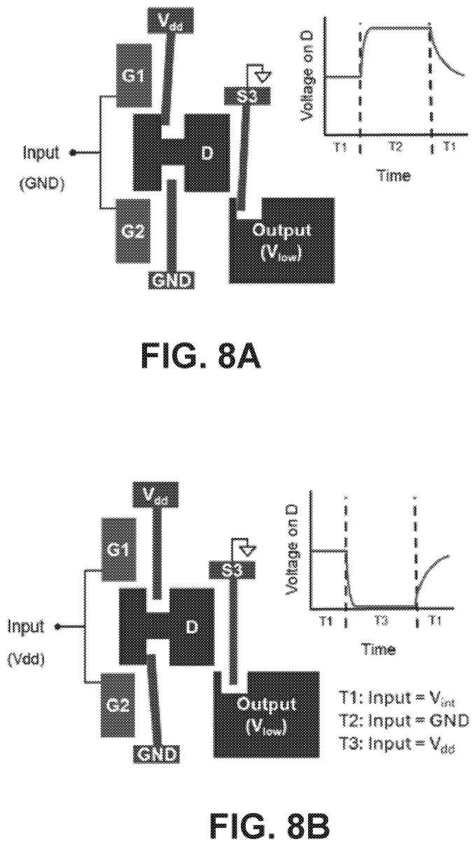

These devices are typically operated with V_{dd}>V_{PI} values ranging approximately from 30 to 60V depending on the relay device dimensions. These values may be stepped down to lower voltages to allow for interfacing with conventional control systems using a single cantilever denoted as S3 in Figures The central drain pad contacted by the complementary high and low voltage cantilevers (denoted as “D” in FIG. 1) serves a dual purpose by also acting as a gate for the S3 cantilever. This drain pad is electrically isolated from the rest of the circuit when neither cantilever is actuated, with pad-to-pad resistance measuring in the tera-ohm range. As such this drain pad will retain the charge applied to it by the S1 or S2 cantilevers even after the cantilevers have been released when the input voltage is at an intermediate state (0<Vᵢₙₜ<V_{dd}) such that none of the cantilevers of the complementary inverter are actuated and the drain pad D is isolated. This charge can slowly leak from the drain pad through a large resistance. The inset graphs in FIGS. 8A and 8B show the voltage across the drain pad and ground to be at some equilibrium point (nonzero) due to leakage currents through the sample. These leakage currents produce a voltage divider effect in which the disconnected drain pad charges to some intermediate potential. When the pull-up, as in FIG. 8A or the pull-down, FIG. 8B, voltage cantilevers actuate, the drain pad is quickly brought to the applied bias. As these cantilevers release, the voltage at the drain slowly returns to this intermediate potential.

When observing outputs from gates employing series and parallel complementary networks, the series network involves more relays on the critical path for generating the logical output. The number of relays on the critical path simultaneously raises output impedance and capacitance, leading to an increase in response time corresponding to the increases in these parameters. In this event, the critical path would be notably longer than the shortest path leading to variations in output parameters depending on the provided inputs. Each input is directed to an individual gate partition, producing the same logical effect as series relays while making the critical path length equal to the shortest path. To illustrate this with the NAND structure depicted in FIG. 3. Applying zero inputs to terminals G1 and G2 will pull both cantilevers connected to S1. As these relays are in parallel, the critical path for this gate consists of only one relay. When one of the gate terminals is at the pull-in voltage, the multi-gate relay at S2 lacks the force required to actuate. Nevertheless, one of the parallel relays still pulls in to yield a high voltage output, maintaining a critical path of one relay. Finally, if both G1 and G2 are at a high voltage, only the multi-gate relay at S2 will actuate, resulting in an output of zero. In this case as well, the critical path remains one relay.

### Pull-Up Resistor Implementation

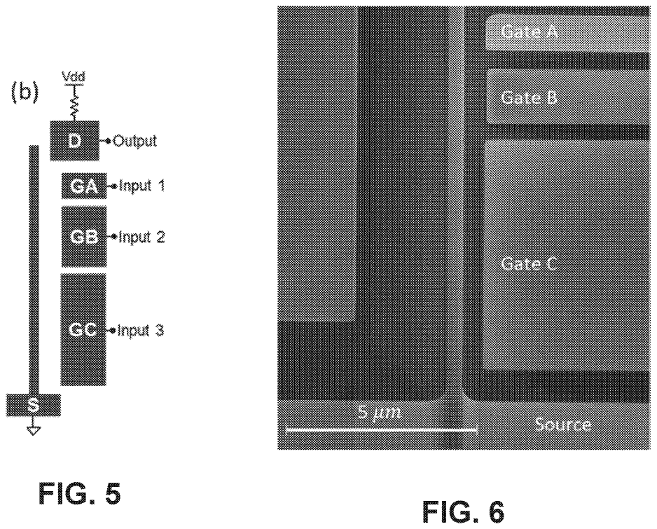

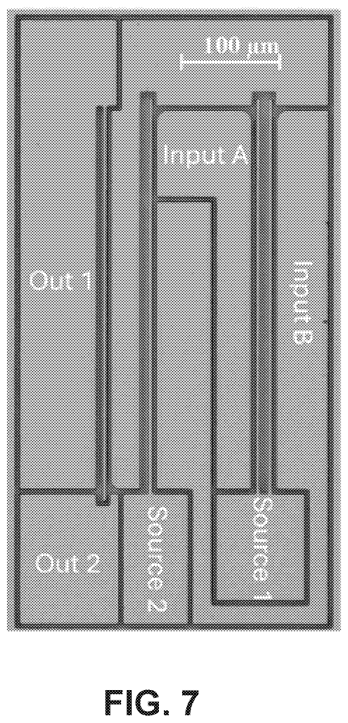

As illustrated in FIG. 5, employing a single multi-gate device and a pull-up resistor as a substitute for a complementary structure. This embodiment can generate a not insignificant on-state current, which may appear counter to some advantages of relay-based logic devices.

The designs follow a single design methodology to achieve the NAND, NOR, and NOT logic functions. A single three terminal relay with a grounded source and a drain biased at the desired logic gate output voltage through a current limiting resistor, serves to invert a signal applied to the gate of the relay when the output is taken directly from the drain.

During operation, a gate voltage greater than or equal to Vpi actuates the cantilever, which pulls the drain and consequently the output to ground. When the cantilever is not actuated, the output is held at the applied bias.

### Design Specifics

N/MEMS relays enable the implementation of complementary logic gates using a unified design approach based on CMOS logic. The device outlined in this document may be configured to fulfil NAND, NOR, and NOT logic functions using a single structure. The output may be inverted, allowing the realization of AND, OR, and buffer functions. These devices may likewise be cascaded to fulfil any combinational logic function. Our unified design approach employs two complementary relay networks. In one network, a number of relays corresponding to the number of inputs are connected in parallel (i.e., all sources are connected at a single node, and all drains connect to a central, electrically isolated pad). The complementary network comprises a single cantilever with a gate divided into a number of partitions corresponding to the number of possible inputs. Referred to as a multi-gate relay, this device only actuates when the voltage across each gate segment and the cantilever is equal to the pull-in voltage (VPI). This is identical in function and used instead of a network of series connected cantilevers to conserve space and stabilize output characteristics (this will be discussed below in detail). The drain of this multi-gate relay connects to the same central pad as the drains of the parallel network. The source/s of one network are biased at a low potential, typically OV while its complement is biased at the VPI, which is potential high enough to actuate a cantilever that is biased at the low voltage.

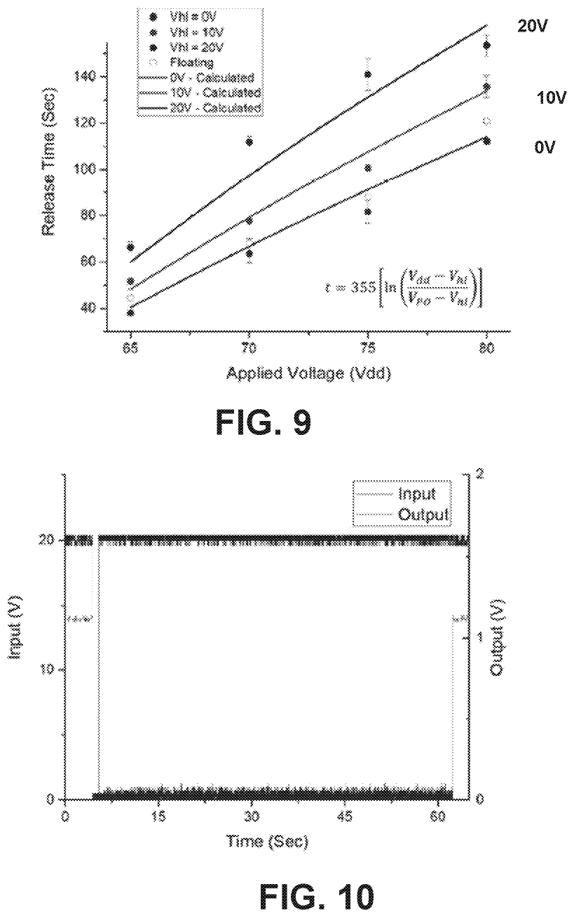

The electrically floating drain pad also functions as the gate of a cascaded cantilever which may be part of another complementary logic gate, or an output relay (as shown in FIGS. 9A and 9B) which is used to step the output voltage down from 30-65 V to ~1 V in order to be compatible with existing electronics. This output cantilever may be configured to invert the output.

Considering FIG. 2 and FIG. 3, AND/NAND logic may be achieved by biasing Source 1 at VPI while grounding Source 2. In this case, the pull-up network is the parallel network of relays. Conversely, OR/NOR logic functions may be implemented by flipping these biases so that the complementary network (i.e., multi-gate relay) now provides the pull-up function. NOT/buffer logic is configured by connecting inputs A and B, irrespective of whether the parallel network or the multi-gate relay is acting as the pull-up or pull-down network. The devices in FIG. 2 and FIG. 3 can allow for up to two inputs, as there are two parallel relays (Source 1), two gate partitions on the Source 2 multi-gate relay, and 2 input terminals. A gate with up to 3 inputs can be implemented by adding a parallel relay, a gate partition, and an input terminal. This same process can be used to create devices with 4 or more inputs. Inverted outputs can be taken by grounding the Out 1 terminal and applying a ~1-5 V bias to Out 2, through a large resistor (1 MΩ used during our testing). The output voltage is then read across the Out 2 terminal and ground. Non-inverted outputs are taken by grounding the Out 1 terminal through a large resistor and applying a bias of ~1-5 V to Out 2. The non-inverted output voltage is then read across the Out 1 terminal and ground. Measured outputs from a NEMS scale device configured as an AND gate and as an OR gate, when supplied with the logical inputs 00, 01, 10, and 11.

Note that for the optimized design, all two-gate combinations provide the same pulling force, i.e., the same required input voltage for actuation.

Also, for a multi-gate relay to function as a logic gate at the optimal capacity with no erroneous actuation due to voltage fluctuations/ripples, the difference in pull-in voltage required when all gates are active versus when one gate is inactive, must be maximized.

This can be accomplished, irrespective of the subgroup of gates that are active, when all gates individually pull-in with equal force. To achieve this condition, various spatial design factors may be considered. The order that this description presents these factors is not intended as any ordering of importance. One factor is that, preferably, the narrowest gate may be structured to avoid its moving, itself, in a cantilever-like manner. As such, it may be preferable to structure the gates to avoid susceptibility to being pushed to or from the neighboring gate, depending on the applied input biases. One reason is that even minor deflections of the gates can also affect the pulling force characteristics of the gate. Another is that the contact of two gates of opposing bias voltages may result in a flow of current of a magnitude that may cause damage to the device, destroy the device. One practice to apply to reduce the likelihood of such phenomena is to use preferable width guidelines of setting gate widths to be larger than the cantilever widths. It will be understood that these guidelines are only examples and that application-specific structural aspects, such as but not limited to stiffness of the device layer material.

One example guideline of the narrowest gate having a deflection preferably less than approximately 2% than that of the cantilever.

Testing Metallization Schemes, Using the Standard Manually Configurable Complementary AND and OR gates.

These contact schemes underwent further testing on manually configurable complementary AND and OR gates. The entire truth table was sequentially tested at 1 s intervals with the gates. This caused each cantilever to be actuated once, including the pull-up cantilever biased at high voltage Vad.

Complementary two-input AND and OR gate I/O timing diagrams measured from manually configurable NEMS devices with TiN/Pt/Ti metallization. Individual Boolean inputs (labeled at the top of the plot) and their corresponding outputs are denoted by dashed lines on the right side of the graph. VPI=50 V for the relays making up the logic gate, 55 V corresponds to logic input of 1, and a logic 1 output is measured at 3.5 V.

The metallization schemes were tested in air, along with the resulting lifetimes of single cantilevers in terms of number of cycles (averaged across three representative devices). The testing results obtained are presented in Table 1 below. During the testing, the handle layer was placed directly on the probe station chuck. On the inventors' observation this indicated Vhl was likely close to ground. Devices were considered nonfunctional when their drain to source resistance exceeded ~2 MΩ. Single cantilevers were tested with 1 V across the drain and source, and the inventors concluded that, for that reason, did not exhibit welding failures.

The inventors concluded the test data showed, for both MEMS and NEMS cantilevers that platinum-based contacts with a thin titanium adhesion layer, Pt/Ti, to be clearly superior compared to platinum contacts placed directly on Si. The inventors concluded that omission of an adhesion layer resulted in a significantly shorter single cantilever lifetime, due to gradual delamination of the contact and the associated increase in contact resistance.

TABLE 1

| | Ti Adhesion | | |
|---|---|---|---|
| | Layer | Metallization | |
| | Thick- | Thick- | Single Cantilever |
| Metallization | ness (nm) | ness (nm) | Lifetime (Cycles) |
| NEMS Pt (no Ti) | 0 | 15 | 3.51E+04 ± 5.59E+03 |
| NEMS Pt/Ti | 5 | 15 | 3.80E+05 ± 9.55E+04 |
| NEMS TiN/Pt/Ti | 5 | 3 ± 15 | 7.97E+05 ± 1.37E+05 |
| NEMS W/Pt/Ti | 5 | 3 ± 15 | 3.92E+06 ± 1.36E+06 |
| MEMS Pt/Ti | 25 | 100 | 4.79E+08 ± 1.72E+08 |
| MEMS TiN/Pt/Ti | 25 | 3 + 100 | 1.59E+09 ± 4.64E+08 |
| MEMS W/Pt/Ti | 25 | 3 + 100 | 1.74E+09 ± 4.35E+08 |

Inventor-conducted tests showed platinum complementary logic gates to succumb to welding approximately four orders of magnitude sooner than single cantilevers. The test data showed that platinum samples without the Ti adhesion layer tended to last for a greater number of cycles than sample having the adhesion layer. Additionally, the test data showed that samples without an adhesion layer tended to fail due to contact degradation as opposed to welding as observed in those with an adhesion layer. The inventors concluded this to suggest that inadequate adhesion between platinum and silicon prompted the metal to detach from the contact, and the detachment prevented the cantilever from welding to the drain but led to significant increase in contact resistance.

Thick (>5 nm) W and TiN contacts were observed to fail due to oxidation as evidenced by a dramatic increase in resistance within 20 cycles, before any welding effects occur.

The inventors concluded that, similar what was shown by the Table 1 results, contacts with thin TiN and W overlayers outperformed other metallization schemes due to the low likelihood of welding associated with the high melting points of W and TiN.

### Fabrication

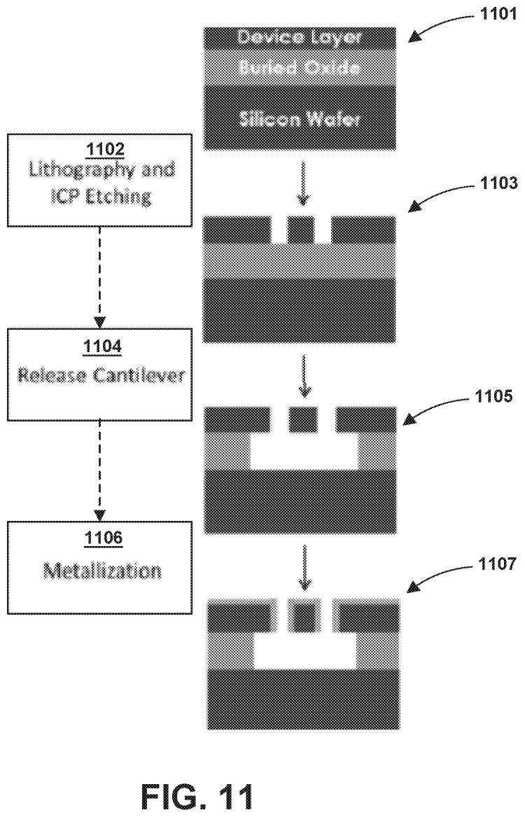

Referring to FIG. 11, N/MEMS logic gate devices are fabricated using a four-step process: lithography, inductively coupled plasma reactive ion etching (ICP RIE), cantilever releasing through wet etching, and metallization.

Devices were fabricated on silicon-on-insulator wafers (SOI) with a device layer thickness of 0.55 μm for NEMS cantilevers and 25 μm for MEMS. The buried oxide layer (BOX) had thickness of 2 and 5 μm for NEMS and MEMS respectively and sat on a 500 μm thick Si handle layer. NEMS devices were patterned using Raith Voyager 50 kV electron beam lithography (EBL) system after spin coating the wafers with ZEP-520A positive electron beam resist. The MEMS samples were patterned using photolithography due to the scaled-up dimensions. The NEMS samples were etched using a RIE-101iPH system from SAMCO Inc. The logic structures required vertical sidewalls with a very low degree of roughness. To accommodate this need, an etching chemistry with a high degree of selectivity with the resist was selected. The specific selected etching chemistry was composed of a pseudo-Bosch process in which SF6 flowed at 19 sccm simultaneously with C4F8 at 15 sccm.

An ICP power and bias power of 60 W and 24 W respectively, was used to achieve an etch rate of approximately 20 nm/min.

The MEMS devices required a cryogenic etch process due to its increased selectivity to account for the ~45-fold increase in device layer thickness. This process was accomplished using a PlasmaPro 100 Estrelas™ ICP-RIE system. This process used SF6 (90 sccm) and O2 (18 sccm) and an ICP power of 600 W with a bias power of 13 W. The etch was performed with a table temperature of −102° C. Both MEMS and NEMS samples were then released using a 49% HF solution to etch the BOX layer. NEMS samples were etched for 1.5 minutes, while MEMS cantilevers were etched for 4 minutes.

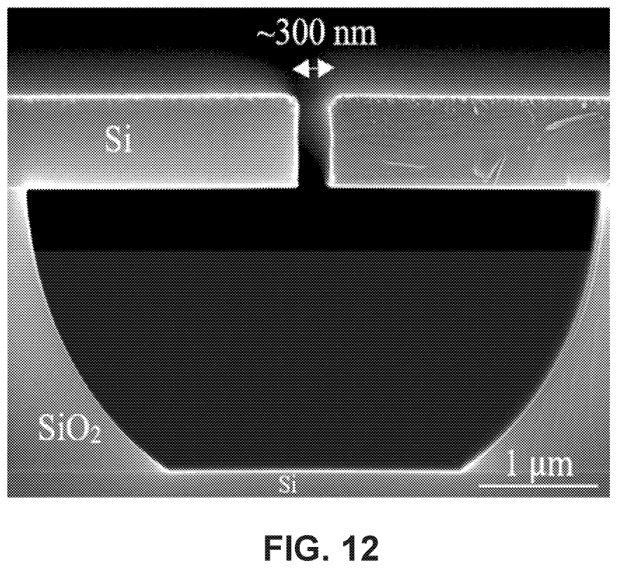

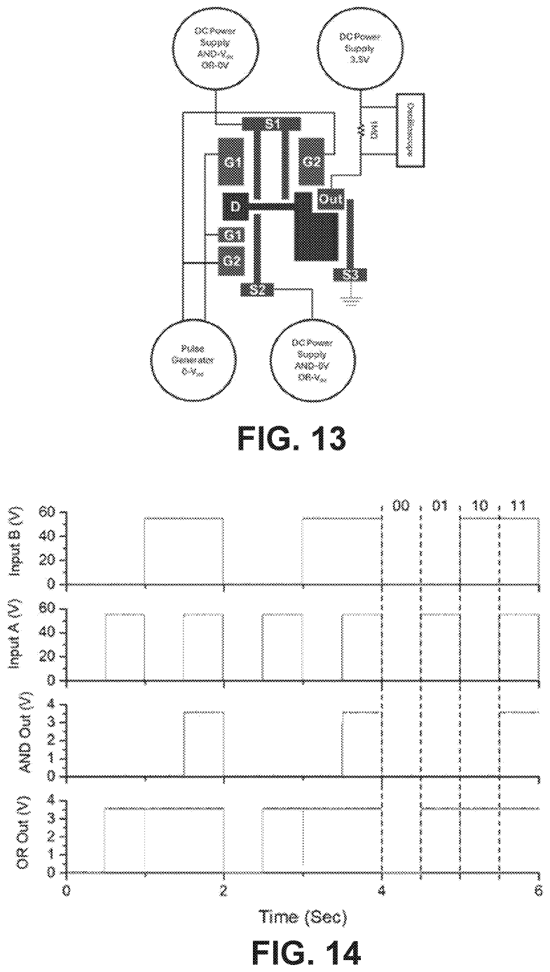

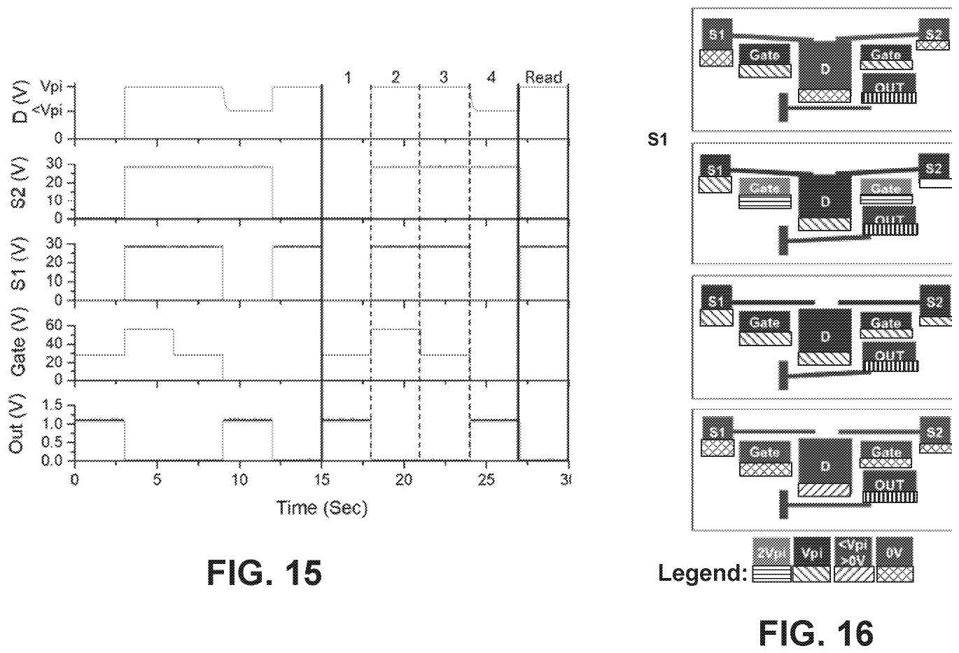

Results of this wet etch are shown in FIG. 12.

N/MEMS devices were metalized via RF sputtering using an RF power of 100 W using an Orion-5 RF sputtering system (AJA International).

Several metallization schemes were tested. The best observed results were achieved with a thin titanium adhesion layer, platinum intermediate layer, and a thin surface layer of tungsten or titanium nitride. For NEMS devices, the specific layer thicknesses were 5 nm, 15 nm, and 3 nm, respectively. For MEMS devices, the corresponding thicknesses were 25 nm, 100 nm, and 3 nm.

The NEMS cantilevers were 11 μm long and 375 nm long.

The MEMS devices were scaled up, to a length of 450 μm and a width of 4 μm. The drain to cantilever gap was 300 nm NEM devices and 4 μm for MEMS devices.

### CONCLUSION

The devices and associated design principles demonstrated novel implementations of N/MEMS technology. N/MEMS logic gates utilizing laterally actuated networks of parallel relays with a complementary multi-gate relay are novel and originally designed, fabricated, and tested by our research group. These novel multi-gate relays were fabricated and tested to allow for 2 or 3 inputs, as shown in FIGS. 2, 3, and 5. Other novel aspects of this design include the ability to perform all principal logic functions (AND, OR, NOT, NAND, NOR, buffer) with a single device layout. The output measurement cantilever which may be configured to invert or not invert the output signal.

Novel multi-gate relays used in the N/MEMS logic structures offer several advantages over similar structures which utilize relays connected in series (drain to source). Principally, this reduces the number of cantilevers needed and device footprint. This also has the advantage of making the critical path the same length as the shortest path.

It is to be understood that practices that are within the scope of the appended claims are not limited to particular embodiments described, as embodiments described herein are susceptible to various modifications and alternative forms. Embodiments are disclosed by way of example in the drawings and are described in detail herein. The example embodiments described, though, are not limited to the particular explicit implementations, configurations, arrangements, and forms disclosed. Rather, the instant disclosure supports all modifications, equivalents, and alternatives that fall within the scope of the appended claims.

It is also to be understood that the terminology used herein is for the purpose of describing particular embodiments only, and is not intended to be limiting, as the scope of exclusivity will be limited only by the appended claims.

Where a range of values is provided, it is understood that each intervening value, to the tenth of the unit of the lower limit unless the context clearly indicates or dictates otherwise, between the upper limit and lower limit of that range and any other stated or intervening value in that stated range, is encompassed within the range. The upper and lower limits of these smaller ranges may independently be included in and encompassed in the smaller ranges, subject to any specifically excluded limit in the stated range. Where the stated range includes one or both of the limits, ranges excluding either or both of those included limits are also included.

Ordinal terms such as “first,” “second,” “third,” etc., as used in this specification and the appended claims to modify, e.g., step(s), functional block(s), signal(s), instruction(s), element(s) are to be understood as a labelling to individually reference separate step(s), functional block(s), signal(s), instruction(s), and/or element(s), and are not to be understood, except where expressly stated or clearly indicated as otherwise, to be any indication of any ordering of the step(s), functional block(s), signal(s), instruction(s), and/or element(s), in terms of time, spatial arrangement, priority, or to be any indication of the presence or inclusion of any of ordinal term referenced step(s), functional block(s), signal(s), instruction(s), and/or element(s) being conditional on the presence or inclusion of any different ordinal term referenced step(s), functional block(s), signal(s), instruction(s), and/or element(s) indication of relative priority.

Unless defined otherwise, all technical and scientific terms used herein have the same meaning as commonly understood by one of ordinary skill in the art(s) to which this disclosure relates.

Representative and illustrative methods and materials are described herein. Methods and materials similar or equivalent to those described herein can also be used in practices according to disclosed embodiments.

It is to be understood that, as used herein and in the appended claims, the singular forms “a”, “an”, and “the” include plural referents unless the context clearly dictates otherwise. It is further noted that the claims may be drafted to exclude any optional element. As such, this statement is intended to serve as support for the recitation in the claims of such exclusive terminology as “solely,” “only” and the like in connection with the recitation of claim elements, or use of a “negative” limitations, such as “wherein [a particular feature or element] is absent”, or “except for [a particular feature or element]”, or “wherein [a particular feature or element] is not present (included, etc.) . . . ”.

As will be apparent to those of skill in the art upon reading this disclosure in its entirety, each of the individual embodiments described and illustrated herein has discrete components and features that may be readily separated from the embodiment or combined with features of any of the other several embodiments without departing from the scope or spirit of the present invention.

It is to be understood that various methods and operations are described as a plurality of separate actions, steps, or operations but it will also be understood that such description can be for further assisting the reader in gaining an understanding of, for example, concepts and/or logic relationships and should not be understood as limiting the order in which the actions, steps, or operations can be performed and that these can be carried out in the temporal order or spatial arrangement recited or in any other order or arrangement that is logically possible.

While the disclosure describes features and aspects in terms of its several exemplary embodiments, those skilled in the art will recognize that the invention can be practiced with modification within the spirit and scope of the appended claims. Accordingly, the appended claims are not limited to the embodiments described above but should further include all modifications and equivalents thereof within the spirit and scope of the description provided herein.

We claim:

1. A multi-gate nano/microelectromechanical (N/MEMS) relay logic device configured to receive a multi-bit input signal and output a logic result, the device comprising:
a drain element, which is conductive;
an N/MEMS multiple gate (MG) relay, configured to couple to a first reference voltage, and to receive a multi-bit input signal, each bit switchable between a logic “0” voltage and a logic “1” voltage and, responsive to a concurrence of logic 1 voltage on all bits of the multi-bit input signal, to couple the first reference voltage to the drain element; and
a complementary network comprising a plurality of N/MEMS relays, configured to couple to a second reference voltage and, responsive to states of the multi-bit input signal having other than concurrence of logic 0 on all bits, to couple the second reference voltage to the drain element, wherein,
the N/MEMS MG relay comprises:
a source element, which is conductive and coupled to the first reference voltage,
a cantilever arm, which is conductive and coupled via the source element to the first reference voltage, and is configured as elastically bendable, from a cantilever arm resting state spaced from the drain element to a cantilever arm deflected state contacting the drain element,
R separate gate elements, each configured as conductive, R being an integer greater than one,
wherein the R separate gate elements are:
arranged proximally to and spaced from the MG cantilever arm, and
configured to receive a corresponding different bit among the R bits of the multi-bit input signal,
wherein the cantilever arm and the R separate gate elements are further and mutually configured such that:
each bit of the multi-bit input that is at logic 1 voltage establishes an incremental pulling force between the r^{th} separate gate element that receives the bit and the cantilever arm, the incremental pulling force being based, at least in part, on the difference between the logic 1 voltage and the first reference voltage,
concurrence of Q bits of the multi-bit input at logic 1 voltage establishes a concurrence of a respective Q of the incremental pulling forces, which combine to be a total pulling force,
responsive to Q being less than R, the total pulling force is insufficient to pull the cantilever arm from the MG cantilever arm resting state to the cantilever arm deflected state, and
responsive to Q being equal to R, the total pulling force is sufficient to pull the cantilever arm from the MG cantilever arm resting state to the cantilever arm deflected state, contacting the drain element, and
the complementary network comprises a plurality of N/MEMS relays, connected in parallel, each having an N/MEMS relay source connector that is coupled to the second reference voltage and each configured to receive a corresponding one of the bits of the multi-bit input signal and, in response to occurrence of any state of the multi-bit input having at least one of the bits at logic 1, to couple the second reference voltage to the drain element.

2. The N/MEMS relay logic device of claim 1, wherein the N/MEMS MG relay is configured as a NEMS scale MG relay, and the cantilever arm is configured as a NEMS scale cantilever arm that includes a three-layer metallization structure comprising a titanium (Ti) adhesion layer, a platinum (Pt) metallization layer, and a titanium nitride (TiN) overlayer.

3. The N/MEMS relay logic device of claim 1, wherein the N/MEMS MG relay is configured as a MEMS scale MG relay, and the cantilever arm is configured as a MEMS scale cantilever arm that includes a three-layer metallization structure comprising a titanium (Ti) adhesion layer, a platinum (Pt) metallization layer, and a tungsten (W) metallization layer.

4. The N/MEMS relay logic device of claim 1, further comprising an N/MEMS output device that is configured as an N/MEMS output relay that includes a step-down cantilever which is arranged, relative to the drain element, such that a voltage difference between the drain element and the step-down cantilever, causes a pulling force between the drain element and the step-down cantilever.

5. The N/MEMS relay logic device of claim 1, wherein:
a first of the R separate gate elements is an MG first gate element, and a second of the R separate gate elements is an MG second gate element,
the MG first gate element is configured to receive a first bit, IN_0, of the multibit input signal, and the MG second gate element is configured to receive a second bit, IN_1, of the multibit input signal,
the MG first gate element is further configured to extend an MG first gate length in a gate length direction, and
the MG second gate element is further configured to extend an MG second gate length in the gate length direction and is aligned with the MG first gate element such that the MG first gate length and the MG second gate length align in series and, in combination, form a total MG gate length.

6. The N/MEMS relay logic device of claim 5, wherein the MG first gate element, the MG second gate element, and the cantilever arm are further configured, mutually, such that:
an IN_0 logic 1 voltage on the MG first gate element concurrent with the first reference voltage on the cantilever arm establishes a first pulling force between the MG second gate element and the cantilever arm, which is based at least in part on the MG first gate length and, based at least I the part on the MG first gate length, is insufficient to pull the cantilever arm from the cantilever arm resting state to the cantilever arm deflected state,
an IN_1 logic 1 voltage on the MG second gate element concurrent with the first reference voltage on the cantilever arm, which is based at least in part on the MG first gate length and, based at least in part on the MG second gate length, is insufficient to pull the cantilever arm from the cantilever arm resting state to the cantilever arm deflected state, and
based at least in part on a combination of the MG first gate length and the MG second gate length, a concurrence of the IN_0 logic 1 voltage on the MG first gate element and the IN_1 logic 1 voltage on the MG second gate element establishes a total pulling force between the MG second gate element and the cantilever arm, which is sufficient to pull the cantilever arm from the cantilever arm resting state to the cantilever arm deflected state.

7. The N/MEMS relay logic device of claim 1, wherein the plurality of N/MEMS relays includes a first N/MEMS relay and a second N/MEMS relay, connected in parallel, and a shared source element which is conductive and is coupled to the second reference voltage and is configured to function as the source for the first N/MEMS relay and the source for the second N/MEMS relay.

8. The N/MEMS relay logic device of claim 7, wherein:
the first N/MEMS relay includes a first N/MEMS relay cantilever arm, which is conductive, and the second N/MEMS relay includes a second N/MEMS relay cantilever arm, which is conductive, and
the first N/MEMS relay cantilever arm extends from the shared source element,
the second N/MEMS relay cantilever arm extends from the shared source element, in a resting state direction parallel to a resting state direction of the first N/MEMS cantilever arm.

9. A method for configuring and fabricating an N/MEMS logic device according to claim 6, the method comprising:
storing in a computer memory:
a simulation model of a device according to claim 1, wherein the simulation model includes a length parameter corresponding to a length of the MG relay cantilever arm, a first gate element length parameter corresponding to the MG first gate length, and
a second gate element length parameter corresponding to the MG second gate length;
performing a simulation process, by a programmable computer connected to the computer memory, wherein the simulation process includes operations using the stored simulation model, that includes iterating values of the first gate element length parameter and iterating values of the second gate a process to identify at least one combination of a usable value or range of usable values of the first gate element length parameter and a usable value or range of usable values of the second gate element length parameter that, in combination, produce simulated deflection responses of the MG cantilever arm values of the IN_0 bit and IN_1 bit that include:
a) in response to each of:
IN_0=logic 1 volts, concurrent with IN_1=logic 0 volts
IN_0=logic 0 volts, concurrent with IN_1=logic 1 volts, and
IN_0=logic 0 volts, concurrent with IN1=logic 1 volts
a simulated bending or deflection of the MG cantilever arm is insufficient to pull the MG cantilever arm to the MG arm deflected state, and
b) in response to
IN_0=logic 1 volts, concurrent with IN1=logic 1 volts
the simulated bending or deflection of the MG cantilever arm indicates the MG cantilever arm being pulled to the MG arm deflected state;
configuring a fabrication process based at least in part on the computed combination of the usable value or usable range of values of the first gate element length parameter and the usable value or usable range of values of the second gate element length parameter; and
fabricating a device according to claim 6, based at least in part on the configured fabrication process.
